(19) United States
(12) Patent Application Publication
(10) Pub. No.: US 2026/0164903 A1
(43) Pub. Date: Jun. 11, 2026

(54) PLANAR ILLUMINATION DEVICE

(71) Applicant: MINEBEA MITSUMI Inc., Nagano (JP)

(72) Inventors: Takahito YOSHIDA, Kitasaku-gun (JP); Ken SUGIYAMA, Kitasaku-gun (JP)

(21) Appl. No.: 19/104,000

(22) PCT Filed: Jul. 12, 2023
(86) PCT No.: PCT/JP2023/025659

§ 371 Date: Feb. 14, 2025

(30) Foreign Application Priority Data
Aug. 23, 2022 (JP) 2022-132288

(51) Int. Cl. H10H 29/856; H10H 29/24; H10H 29/85; H10H 29/855

(52) U.S. Cl. CPC H10H 29/856; H10H 29/24; H10H 29/8517; H10H 29/855

(57) ABSTRACT

A planar illumination device according to an embodiment comprises a substrate, a plurality of light sources in a first group, and one or more light sources in a second group. Prescribed electrical wiring is applied to the substrate. The plurality of light sources in the first group are disposed across substantially the entire surface of the substrate. The one or more light sources in the second group are disposed adjacent to the plurality of light sources in the first group within a prescribed region on the substrate.

### CROSS REFERENCE TO RELATED APPLICATIONS

This application is a national stage entry of International Application No. PCT/JP 2023/025659, filed on Jul. 12, 2023, which claims priority to Japanese Patent Application 2022-132288, filed on Aug. 23, 2022, which is incorporated herein by reference.

### TECHNICAL FIELD

The present disclosure relates to a planar illumination device.

### BACKGROUND

There are cluster meters including a collection of various meters required during travel, such as a speedometer, a tachometer, and an odometer of an automobile (refer to JP 9-301065 A, for example). Such a cluster meter includes telltale parts such as warning lights. These telltale parts are subject to color specifications by law and are required to be visible in any environment, such as, when exposed to direct sunlight or the like, to not lack luminance.

Nowadays, such a cluster meter performs display with a high degree of freedom by a liquid crystal panel and a backlight. However, the telltale parts, requiring high luminance and high color-rendering properties, are often provided independently of the liquid crystal panel. That is, a telltale part is constituted by a light-shielding member having a cutout of an icon shape to be displayed and a single-color light-emitting diode (LED) corresponding to the specified display color and disposed directly beneath the light-shielding member.

Note that, although not a telltale part itself of a cluster meter, display devices provided with a different backlight in order to display a fixed pattern, such as a touch switch pattern, next to a non-fixed pattern, such as map information or an in-vehicle camera image, have also been disclosed (refer to JP 2019-152748 A, for example). Alternatively, although a warning display for an approaching vehicle may be provided separately for the rear, displays using liquid crystal panels and backlights are also becoming more common for door mirrors and rearview mirrors and, in some cases, the display device includes a telltale part for a proximity warning display or the like.

### SUMMARY

As described above, when a telltale part of a cluster meter is provided separately from a liquid crystal panel and a backlight of the liquid crystal panel for other parts, or when a telltale part of a door mirror or a rearview mirror is provided separately from a liquid crystal panel and a backlight of the liquid crystal panel for other parts, the structure is complicated, making cost reduction difficult. Further, a telltale part cannot be utilized for other displays, resulting in a problem in that the display screen is not sufficiently utilized and a degree of freedom of the screen display cannot be enhanced.

The present disclosure has been made in view of the above circumstances, and an object of the present disclosure is to provide a planar illumination device applicable as a backlight of a cluster meter, a door mirror, a rearview mirror, or the like including a telltale part, capable of meeting the requirements of high luminance and high color-rendering properties as with a telltale part or the like, and capable of effectively utilizing a display screen and improving a degree of freedom of screen display with a simple structure.

To solve the above-described problems and achieve the object, a planar illumination device according to an aspect of the present disclosure includes a substrate, a plurality of first light sources, and one or more second light sources. The plurality of first light sources are disposed in a first region of the substrate. The one or more second light sources are disposed at a position different from the first light sources in a second region within the first region.

A planar illumination device according to an aspect of the present disclosure is applicable as a backlight of a cluster meter, a door mirror, a rearview mirror, or the like including a telltale part, is capable of meeting the requirements of high luminance and high color-rendering properties as with a telltale part or the like, and is capable of effectively utilizing a display screen and improving a degree of freedom of screen display with a simple structure.

### BRIEF DESCRIPTION OF DRAWINGS

FIG. 1 is an external perspective view of a planar illumination device according to an embodiment.

FIG. 2 is an exploded perspective view illustrating a main part of the planar illumination device.

FIG. 3 is a plan view illustrating only a substrate and a reflector.

FIG. 4 is a cross-sectional view taken along line X-X of the planar illumination device in FIG. 1.

FIG. 5 is a diagram showing examples and improvements of the effects of adding light sources of a second group and removing a part of reflecting walls of the reflector on luminance uniformity.

FIG. 6 is an external perspective view illustrating an example in a state of a liquid crystal panel being mounted on the planar illumination device.

FIG. 7 is a view illustrating an example of a telltale part displayed on the liquid crystal panel.

### DESCRIPTION OF EMBODIMENTS

Hereinafter, a planar illumination device according to embodiments will be described with reference to the drawings. Note that this disclosure is not limited by these embodiments. Further, the dimensional relationships between elements, proportions of the elements, and the like in the drawings may differ from reality. The drawings may include parts with dimensional relationships and scales different from each other between drawings. Furthermore, the contents described in one embodiment or modification are likewise applied in principle to other embodiments or modifications.

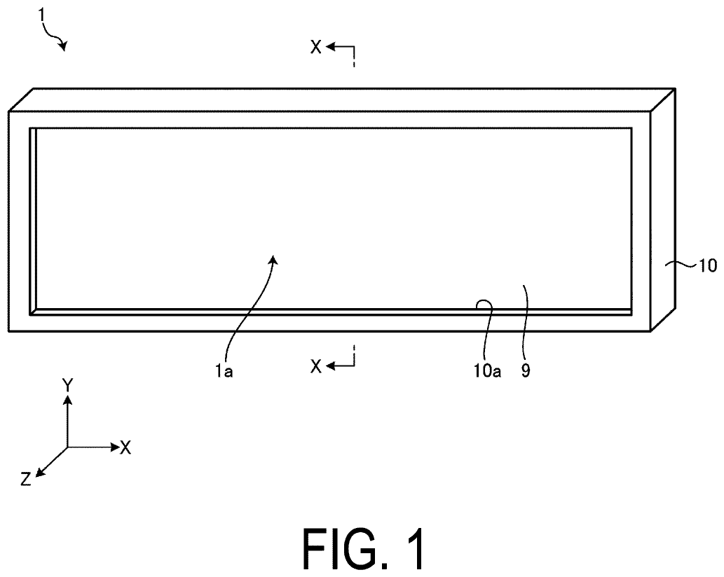

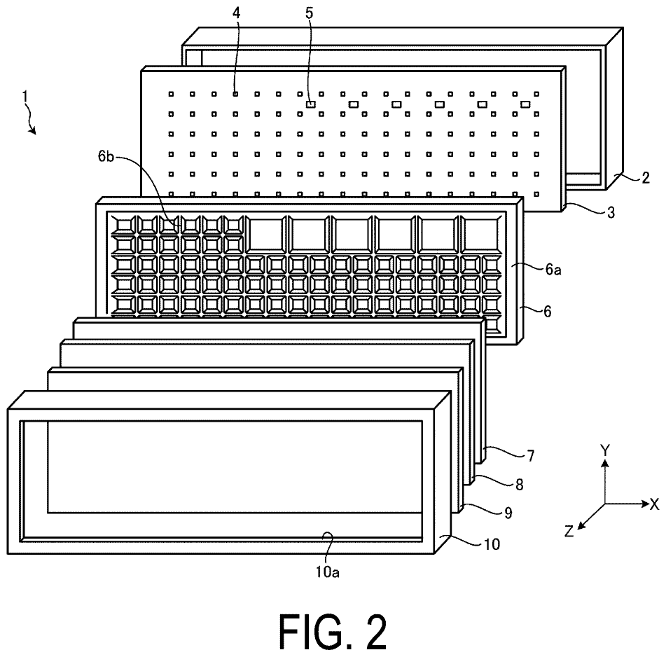

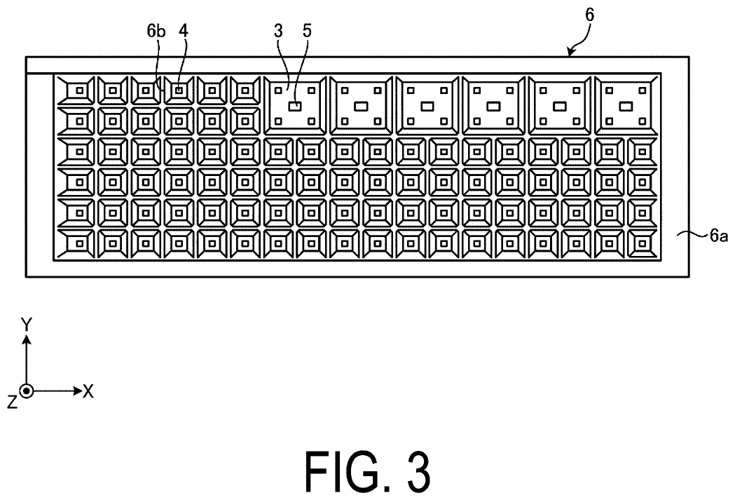

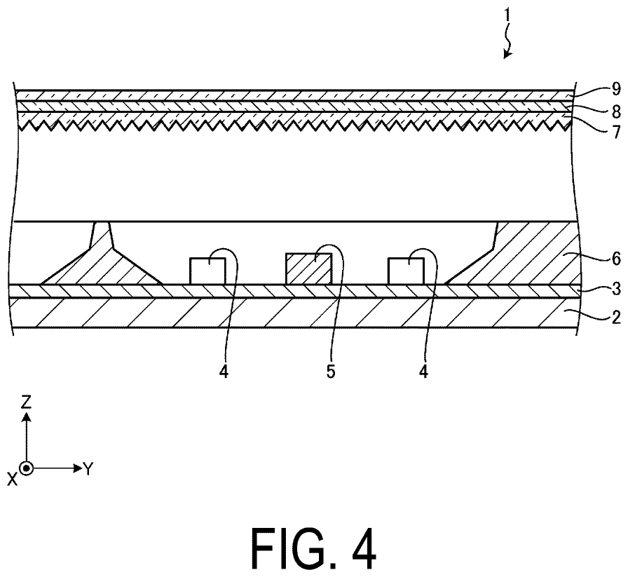

FIG. 1 is an external perspective view of a planar illumination device 1 according to an embodiment. In the drawing, for the sake of convenience, a longitudinal direction of the planar illumination device 1 is an X-axis direction, a lateral direction is a Y-axis direction, and a thickness direction is a Z-axis direction, but an orientation during use is arbitrary. FIG. 2 is an exploded perspective view illustrating a main part of the planar illumination device 1 as viewed from an emission surface side as in FIG. 1. FIG. 3 is a plan view illustrating only a substrate 3 and a reflector 6. FIG. 4 is a cross-sectional view taken along line X-X of the planar illumination device 1 in FIG. 1, and illustrates a cross section of part of the upper side in FIG. 1.

In FIG. 1, the planar illumination device 1 has a substantially rectangular (or substantially square) and substantially plate-like external shape and has a housing composed of a bottom frame (hidden at the rear side in the drawing) having a bottomed box shape accommodating a substrate and the like described below and a top frame 10 covering an opening side of the bottom frame. In the top frame 10, an emission surface la is formed by an opening 10a having a substantially rectangular shape, causing light to be emitted from the inside toward the outside of the planar illumination device 1. In FIG. 1, a polarized light-reflecting film 9 inside the planar illumination device 1 is exposed at the emission surface 1a. When the planar illumination device 1 is used as a backlight of an in-vehicle cluster meter, door mirror, rearview mirror, or the like, the liquid crystal panel and the like are mounted on the emission surface 1a side.

In FIG. 2, in the planar illumination device 1, the substrate 3 provided with a plurality (large number) of light sources 4 of a first group and one or more (six in the example illustrated) light sources 5 of a second group, the reflector 6, a diffuser 7, a prism sheet 8, and the polarized light-reflecting film 9 are attached to a bottom frame 2, and the top frame 10 is fitted on an outer side of the bottom frame 2 in a covering manner.

The bottom frame 2 includes a bottom part, and side walls of four sides provided at an outer periphery of the bottom part. The bottom frame 2 is formed of a die casting, a sheet metal, or the like. The substrate 3 is fixed inside a bottom part of the bottom frame 2 via a fixing member (not illustrated) composed of double-sided tape or the like.

The light sources 4 of the first group composed of a plurality (large number) of light-emitting diodes (LEDs) or the like are disposed in, for example, a grid form on the substrate 3. Further, the one or more light sources 5 of the second group are disposed adjacent to the plurality of light sources 4 of the first group in a predetermined region on the substrate 3, for example, in part of the long side on the upper side in the drawing. Each of the light sources 5 of the second group is disposed at a center of four of the light sources 4 of the first group (without interfering with the light sources 4 of the first group) respectively disposed at corners of a virtual rectangle, for example. An electrical wiring line supplying electric power to the light sources 4, 5 is provided on the substrate 3. Light emission of the light sources 4, 5 can be individually controlled.

Between the light sources 4 of the first group on the substrate 3, a rear surface of the reflector 6 is fixed via a fixing member (not illustrated) composed of a plurality of belt-shaped pieces of double-sided tape or the like extending in a left-right direction (or up-down direction) in FIG. 2.

The reflector 6 is for increasing luminance by reflecting, to the emission surface side, light emitted from the light sources 4 of the first group. The reflector 6, at an outer edge, is surrounded by a frame 6a also serving as a reflecting wall. A plurality of (many) segments, each surrounded by four reflecting walls 6b are formed inside the frame 6a. Most of these are segments (first segments) corresponding to the individual light sources 4 of the first group. A part corresponding to a telltale part or the like of a warning light or the like is a segment corresponding to four of the light sources 4 of the first group aligned vertically and horizontally with one light source 5 of the second group at the center. In a segment corresponding to a telltale part or the like (second segment), four of the reflecting walls 6b between the four light sources 4 of the first group are removed, and the light source 5 of the second group is disposed at a space formed by the removal of the four reflecting walls 6b. As a result, the four light sources 4 of the first group and the one light source 5 of the second group at the center are surrounded by four of the reflecting walls 6b (with one being part of the frame 6a). The reflector 6 is manufactured by injection molding a synthetic resin or the like. Note that, although the four reflecting walls 6b are entirely removed in the above embodiment, part of each of the four reflecting walls 6b may be left as long as the space for arranging the light source 5 of the second group can be secured. Further, the arranged positions of the second segments are as desired. For example, the first segments may be interposed between adjacent second segments, or the second segments may be provided at positions inwardly away from the frame 6a. When an overall shape of the reflector 6 is an irregular shape in plan view, the second segments may be provided only in a rectangular part excluding an irregular part. Further, a plurality of the second segments may correspond to one icon.

Further, the plurality of light sources 4 of the first group are elements emitting light from side surfaces, and the one or more light sources 5 of the second group are elements emitting light from top surfaces. That is, the light emitted from the side surfaces of the light sources 4 in the first group is reflected by the reflecting walls 6b of the reflector 6 and emitted in a direction substantially normal to the emission surface. Further, the light emitted from the top surfaces of the light sources 5 of the second group is directly emitted in the direction substantially normal to the emission surface.

The diffuser 7 disposed at the emission side of the reflector 6 diffuses light passing through the diffuser 7, thereby reducing luminance unevenness. Note that, at an incident side (light source 4, 5 side and reflector 6 side) of the diffuser 7, there are provided a plurality of minute pyramid prisms with vertices of quadrangular pyramids (vertices not in contact with bottom surfaces) facing the light source 4, 5 side and the bottom surfaces facing the emission side. The pyramid prisms may be provided across an overall surface of the diffuser 7, or may be provided only in the region corresponding to the telltale parts provided with the light sources 5 of the second group. Note that, separate from the diffuser 7, an optical sheet provided with a plurality of the pyramid prisms may be disposed at the incident side of the diffuser 7.

The pyramid prisms diffuse the light emitted from the side surfaces of the light sources 4 of the first group and reflected by the reflecting walls 6b of the reflector 6 and the light emitted from the top surfaces of the light sources 5 of the second group to the surroundings, thereby reducing luminance unevenness. Note that, depending on specifications related to luminance uniformity, the diffuser 7 does not necessarily need to be provided with the pyramid prisms, and prisms having a shape other than a pyramid may be provided.

The prism sheet 8 disposed at the emission side of the diffuser 7 improves luminance by adjusting a light distribution.

The polarized light-reflecting film 9 disposed at the emission side of the prism sheet 8 transmits polarized light in a predetermined direction, reflects polarized light in a direction perpendicular to the predetermined direction, and is aligned with a polarization direction of a liquid crystal panel mounted outside.

The top frame 10 is disposed at the emission surface side of the polarized light-reflecting film 9, and the top frame 10 is fixed to the bottom frame 2. The top frame 10 is formed of a die casting, a sheet metal and the like.

Note that the planar illumination device 1 having a planar shape is illustrated in the drawing, but the planar illumination device 1 may have a curved shape. In this case, for example, the bottom frame 2, the substrate 3, the reflector 6, and the top frame 10 are formed in a curved shape, and the diffuser 7, the prism sheet 8, and the polarized light-reflecting film 9 are deformed in a curved shape during assembly.

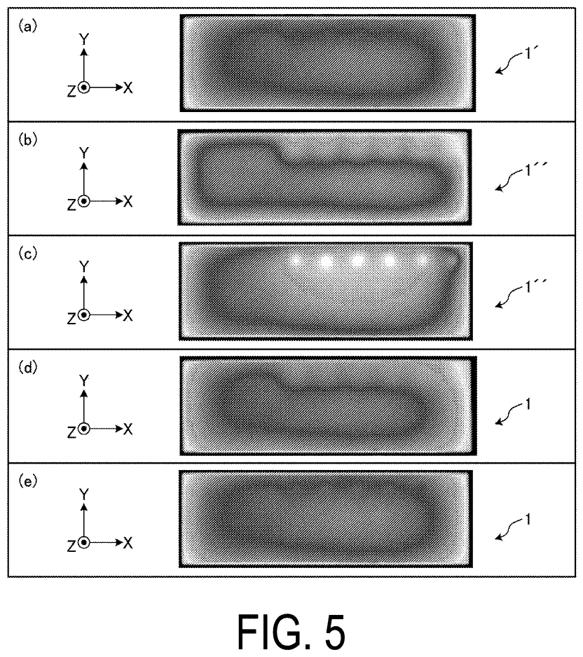

FIG. 5 is a diagram showing examples and improvements of the effects of adding the light sources 5 of the second group and removing a part of the reflecting walls of the reflector 6 on luminance uniformity. An upper row (a) is a plan view showing an example of a luminance distribution of a planar illumination device 1′ according to a first comparative example. In this comparative example, the light sources of the second group are not provided and a part of the reflecting walls of the reflector are not removed. In this case, although there is a slight decrease in luminance around the periphery, luminance uniformity is maintained in most parts.

A second row (b) from the top is a plan view illustrating an example of a luminance distribution in a planar illumination device 1″ of a second comparative example. In this comparative example, the light sources of the second group are provided and a part of the reflecting walls of the reflector is removed, but only the light sources of the first group are turned on. In this case, although luminance unevenness occurs near the upper long side due to the removal of the reflecting walls of the reflector, the number and arrangement positions of the light sources of the first group are the same as in the first comparative example, making the effect minimal. Note that, although the second comparative example with the light sources of the second group provided and a part of the reflecting walls of the reflector removed is slightly inferior in luminance uniformity as compared with the luminance uniformity of the embodiment illustrated in FIG. 1 to FIG. 4, the example can be adopted as another embodiment.

A third row (c) from the top is a plan view showing an example of a luminance distribution in the planar illumination device 1″ of the second comparative example. In this comparative example, the light sources of the second group are provided and a part of the reflecting walls of the reflector are removed. Here, the light sources of the first group and the light sources of the second group are turned on. In this case, in addition to the gentle luminance distribution in (b), a peaky luminance distribution by the light sources of the second group being turned on is recognized, and high luminance of the telltale parts can be expected.

A fourth row (b) from the top is a plan view showing an example of a luminance distribution in the planar illumination device 1 of the embodiment of FIG. 1 to FIG. 4. In this example, only the light sources 4 of the first group are turned on. In this case, as compared with the luminance distribution of (b), the luminance unevenness is reduced by the diffusion effect of the pyramid prisms of the diffuser 7.

A fifth row (e) from the top is a plan view showing an example of a luminance distribution in the planar illumination device 1 of the embodiment of FIG. 1 to FIG. 4. In this example, the light sources 4 of the first group and the light sources 5 of the second group are turned on. In this case, as compared with the luminance distribution of (c), the peaky luminance distribution is eliminated by the diffusion effect of the pyramid prisms of the diffuser 7. Accordingly, employment of the diffuser including the pyramid prisms is effective when luminance uniformity is prioritized over magnitude.

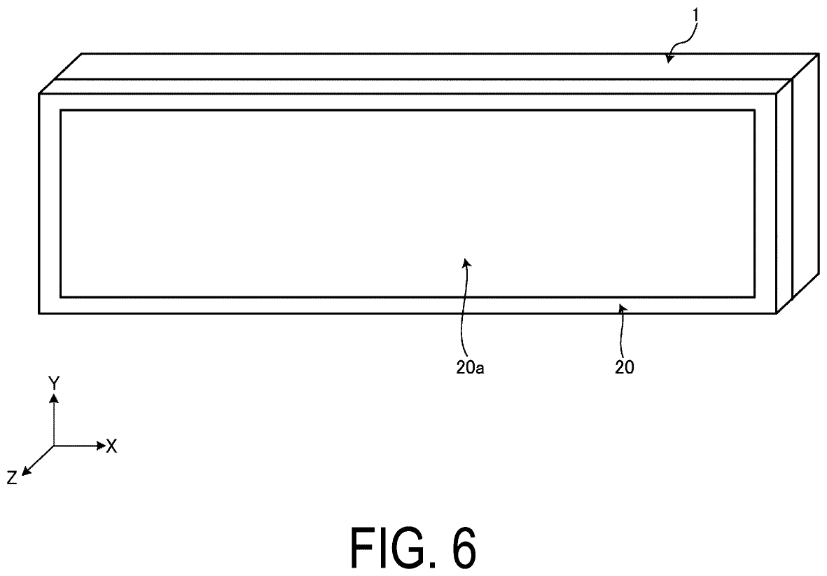

FIG. 6 is an external perspective view illustrating an example in a state of a liquid crystal panel 20 being mounted on the planar illumination device 1. The front side in the drawing is a display surface 20a of the liquid crystal panel 20. The liquid crystal panel 20 may be a color liquid crystal panel or a monochromatic liquid crystal panel.

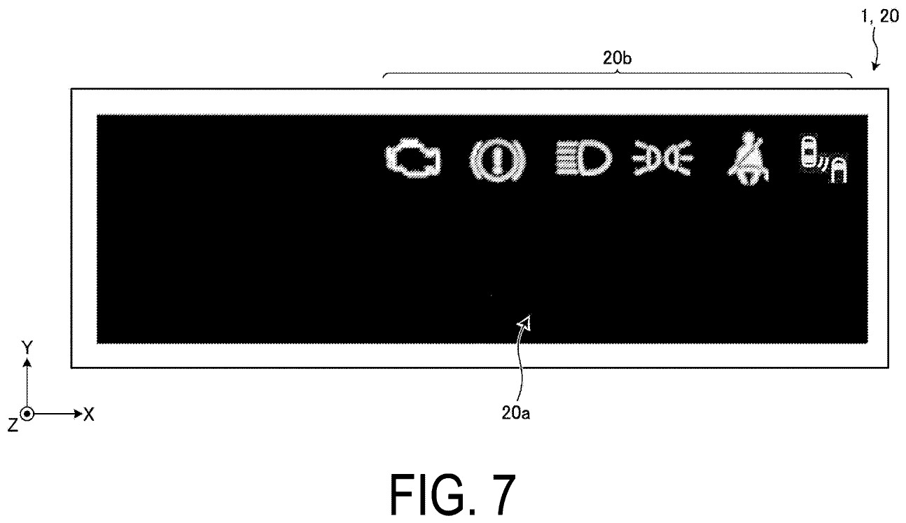

FIG. 7 is a view illustrating an example of a telltale part 20b displayed on the liquid crystal panel 20. When a color liquid crystal panel is disposed as the liquid crystal panel 20, the light sources 4 of the first group and the light sources 5 of the second group may emit white light or pseudo-white light. In this case, shapes and colors of the various warning lights in the telltale part 20b are represented by images reproduced by the color liquid crystal panel, and the various warning lights are displayed by being illuminated from behind with white or pseudo-white light from the light sources 5 of the second group. Further, not only the light sources 5 of the second group but also the light sources 4 of the first group in the surrounding area are turned on at the same time, making it possible to further increase the luminance of the display of the warning lights. Note that, even when a color liquid crystal panel is used, the luminance of the warning lights can be further increased by making the light sources 5 of the second group emit light in colors corresponding to the displayed icons.

Note that at least one of the light sources 4, 5 of the first group and the second group may be a light-emitting light source obtained by integrating the single-color LEDs of red, green, and blue (RGB) into one. LEDs obtained by integrating respective light-emitting chips of RGB into one package are commercially available. White light is obtained when the light-emitting chips of RGB are simultaneously turned on, and single-color light of any one of RGB is obtained when any one of the light-emitting chips of RGB is turned on. By changing the ratio of light-emission amounts of the RGB chips, it is possible to obtain a single-color light of any color. This makes it possible to integrate elements of the light sources.

Further, when a monochromatic liquid crystal panel is disposed as the liquid crystal panel 20, the light sources 4 of the first group may emit light in white, pseudo-white, or a predetermined color, and the light sources 5 of the second group may emit light in colors (including white and pseudo-white) corresponding to the displayed icons. In this case, the shapes of the various warning lights in the telltale part 20b are represented by the images reproduced by the monochromatic liquid crystal panel, and the colors of the various warning lights are represented by the colors of the illumination provided by the light sources 5 of the second group from behind. Note that, in this case as well, at least one of the light sources 4, 5 of the first group and the second group may be a light-emitting light source obtained by integrating the single-color LEDs of red, green, and blue (RGB) into one.

Further, regardless of whether a color liquid crystal panel or a monochromatic liquid crystal panel is disposed as the liquid crystal panel 20, it is possible to display desired images (speedometer, tachometer, map image, television image, or the like) across an entire surface of the display surface 20a including the telltale part 20b. In this case, illumination from the planar illumination device 1 is performed by the light sources 4 of the first group. Further, in the telltale part 20b, icons corresponding to warning lights or the like in predetermined colors can be displayed superimposed on images of other parts. Note that, to ensure visibility of the icons, when the icons are displayed superimposed on the various meters or the like, the icons may be formed by arranging symbols on a black background, the displays of the various meters or the like at the superimposed part may be turned off, or the telltale part 20b and the various meters or the like may be alternately displayed. Further, in the case of use as a cluster meter, in addition to the telltale part 20b, display of various meters such as a speedometer and a tachometer required during travel can be performed in parts other than the telltale part 20b. Further, in the case of use as a door mirror or a rearview mirror, in addition to the telltale part 20b, display of camera-captured images such as a rear side image can be performed in parts other than the telltale part 20b.

Although the embodiments of the present disclosure have been described above, the present disclosure is not limited to the above-mentioned embodiments and may be modified in various ways without departing from the gist of the disclosure.

Thus, a planar illumination device according to an embodiment includes a substrate provided with a predetermined electrical wiring line, a plurality of light sources of a first group disposed across substantially an entire surface of the substrate, one or more light sources of a second group disposed adjacent to the plurality of light sources of the first group in a predetermined region of the substrate. Accordingly, the planar illumination device is applicable as a backlight of a cluster meter, a door mirror, a rearview mirror, or the like including a telltale part, is capable of meeting the requirements of high luminance and high color-rendering properties as with a telltale part or the like, and is capable of effectively utilizing a display screen and improving a degree of freedom of screen display with a simple structure.

That is, the telltale part or the like is mainly illuminated by the light source(s) of the second group and elements other than the telltale part or the like are illuminated by the light sources of the first group, making use as a backlight of a cluster meter, a door mirror, a rearview mirror, or the like including a telltale part possible. Further, the light source(s) of the second group are provided separately from the light sources of the first group, making it possible to easily increase the luminance of the light source(s) of the second group and emit light in an any color, and thus meet the requirements of high luminance and high color-rendering properties of a telltale part or the like. Further, the light sources of the first group and the light source(s) of the second group are disposed on one substrate, simplifying the structure and reducing cost. Further, the entire screen can be utilized for elements other than the telltale part or the like by the light sources of the first group, making it possible to effectively utilize the display screen. Further, the telltale part or the like and other displays are performed by the liquid crystal panel provided at the emission side, and the light-shielding member or the like having a cutout of an icon shape dedicated to the telltale part is not required, making it possible to improve the degree of freedom of screen display.

Further, the plurality of light sources of the first group are disposed in a grid form across substantially the entire surface of the substrate, and the one or more light sources of the second group are disposed between the light sources of the first group adjacent to each other. Accordingly, the plurality of light sources of the first group can be disposed as in the related art not including a telltale part, making it possible to exhibit functionality as a backlight of the telltale part or the like while maintaining functionality as a backlight of the cluster meter or the like.

Further, the planar illumination device includes a reflector including a reflecting wall surrounding each of the plurality of light sources of the first group. The plurality of light sources of the first group are disposed in a grid form across substantially the entire surface of the substrate, a light source of the second group is disposed at a center of four of the light sources of the first group vertically and horizontally adjacent to each other, and at least part of four of the reflecting walls between the four light sources of the first group, with the light source of the second group disposed at the center, is removed. This makes it possible to additionally arrange the light sources of the second group while improving the luminance by the reflector.

Further, the plurality of light sources of the first group are elements emitting light from side surfaces, and the one or more light sources of the second group are elements emitting light from top surfaces. This makes it possible to emit light according to the presence or absence of the reflecting walls of the reflector. That is, the light sources of the first group emit light toward the reflecting walls, and the light source(s) of the second group not surrounded by the reflecting walls emit light toward the emission side, making it possible to effectively achieve a light distribution in the substantially normal direction.

Further, an optical sheet provided with a plurality of minute pyramid prisms with apexes facing the light source side is provided at an emission side. Accordingly, luminance unevenness due to the addition of the one or more light sources of the second group and luminance unevenness due to the removal of the reflecting walls of the reflector are reduced by a diffusion effect of the pyramid prisms, increasing luminance uniformity.

Further, a color liquid crystal panel is disposed at an emission side, the plurality of light sources of the first group emit light in white or pseudo-white, and the one or more light sources of the second group emit light in white, pseudo-white, or a predetermined color corresponding to an icon. Accordingly, the emitted color required by the telltale part or the like is realized by the emitted color of the color liquid crystal. Further, by causing not only the light source(s) of the second group but also the light sources of the first group around the periphery to emit light, it is possible to increase the luminance at the telltale part or the like. One or more of the light sources of the first group and the second group may be a light-emitting light source obtained by integrating red, green, and blue single-color LEDs into one.

Further, when a predetermined region of the substrate is illuminated, light emission is performed by the one or more light sources of the second group disposed in the predetermined region, or light emission is performed by the plurality of light sources of the first group disposed in the predetermined region and the one or more light sources of the second group disposed in the predetermined region. This makes it possible to display a telltale part or the like by light emission of the light source(s) of the second group, and increase the luminance by adding the light sources of the first group.

Further, a monochromatic liquid crystal panel is disposed at an emission side, the plurality of light sources of the first group emit light in white, pseudo-white, or a predetermined color, and the one or more light sources of the second group emit light in a color corresponding to an icon displayed in the predetermined region. Accordingly, the emitted color required by the telltale part or the like is realized by the emitted color(s) of the light source(s) of the second group. One or more of the light sources of the first group and the second group may be a light-emitting light source obtained by integrating red, green, and blue single-color LEDs into one.

Further, the light sources of the first group and/or the second group are light-emitting light sources obtained by integrating single color LEDs of red, green, and blue into one. This makes it possible to integrate elements of the light sources.

Further, the planar illumination device according to the embodiment can be applied to, for example, a warning light display of a door mirror or a rearview mirror in addition to a warning display of a cluster meter. Further, application can also be made to a blind spot warning (warning indicating a vehicle is approaching from the rear or side).

In addition, the present disclosure is not limited to the embodiments described above. A configuration obtained by appropriately combining the above-mentioned components is also included in the present disclosure. Furthermore, further effects and modifications can be easily derived by a person skilled in the art. Thus, a wide range of aspects of the present disclosure is not limited to the embodiments described above and may be modified variously.

While preferred embodiments of the disclosure have been described above, it is to be understood that variations and modifications will be apparent to those skilled in the art without departing from the scope and spirit of the disclosure. The scope of the disclosure, therefore, is to be determined solely by the following claims.

1. A planar illumination device comprising:
a substrate;
a plurality of first light sources disposed in a first region of the substrate; and
one or more second light sources disposed at a position different from the first light sources in a second region within the first region.

2. The planar illumination device according to claim 1, wherein
the plurality of first light sources are disposed in a grid form in the first region, and
the one or more second light sources are disposed between the plurality of first light sources in the second region.

3. The planar illumination device according to claim 1, comprising
a reflector including reflecting walls surrounding each of the plurality of first light sources, wherein
the plurality of first light sources are disposed in a grid form,
each of the one or more second light sources is disposed at a center of four of the first light sources vertically and horizontally adjacent to each other, and
at least part of four of the reflecting walls between the four first light sources, with each of the second light sources disposed at the center, is removed.

4. The planar illumination device according to claim 1, wherein
the plurality of first light sources are elements emitting light from side surfaces, and
the one or more second light sources are elements emitting light from top surfaces.

5. The planar illumination device according to claim 1, wherein
an optical sheet provided with a plurality of minute pyramid prisms with apexes facing the substrate is provided at an emission side of the substrate.

6. The planar illumination device according to claim 1, wherein
a color liquid crystal panel is disposed at an emission side,
the plurality of first light sources emit light in white or pseudo-white, and
the one or more second light sources emit light in white, pseudo-white, or a predetermined color corresponding to an icon.

7. The planar illumination device according to claim 6, wherein
when the second region of the substrate is illuminated, light emission is performed by the one or more second light sources disposed in the second region, or light emission is performed by the plurality of first light sources disposed in the second region and the one or more second light sources disposed in the second region.

8. The planar illumination device according to claim 1, wherein
a monochromatic liquid crystal panel is disposed at an emission side,
the plurality of first light sources emit light in white, pseudo-white, or a predetermined color, and
the one or more second light sources emit light in a color corresponding to an icon displayed in the second region.

9. The planar illumination device according to claim 1, wherein,
the first light sources and/or the second light sources are light-emitting light sources obtained by integrating single-color LEDs of red, green, and blue into one.

10. A planar illumination device comprising:
a substrate;
a plurality of light sources of a first group disposed across substantially an entire surface of the substrate;
one or more light sources of a second group disposed adjacent to the plurality of light sources of the first group in a predetermined region of the substrate; and
a reflector including reflecting walls surrounding each of the plurality of light sources of the first group, wherein
the plurality of light sources of the first group are disposed in a grid form across substantially the entire surface of the substrate,
a light source of the second group is disposed at a center of four of the light sources of the first group vertically and horizontally adjacent to each other, and
at least part of four of the reflecting walls between the four light sources of the first group, with the light source of the second group disposed at the center, is removed.
